(19) United States
(12) Patent Application Publication
(10) Pub. No.: US 2025/0355050 A1
(43) Pub. Date: Nov. 20, 2025

(54) COMMUNICATION DEVICE, COMMUNICATION METHOD, AND POWER STORAGE SYSTEM

(71) Applicant: YAZAKI CORPORATION, Tokyo (JP)

(72) Inventor: Masaya Hatakeyama, Susono-shi (JP)

(21) Appl. No.: 19/281,474

(22) Filed: Jul. 25, 2025

Related U.S. Application Data
(63) Continuation of application No. PCT/JP2024/004090, filed on Feb. 7, 2024.

(30) Foreign Application Priority Data
Feb. 28, 2023 (JP) 2023-030007

(51) Int. Cl. G01R 31/382; H04L 12/40

(52) U.S. Cl. CPC G01R 31/382; H04L 12/40; H04L 2012/40215

(57) ABSTRACT

In a power storage system in which a CAN data frame including information about states of a plurality of storage batteries and a CAN ID is transmitted from the storage batteries to a state monitoring device via a CAN, the state monitoring device can acquire the information about the states of the plurality of storage batteries. The communication device (100) includes a CAN ID conversion device (101-1) configured to convert the CAN ID included in the CAN data frame into a BMS ID for identifying state information of a battery B1 and the battery.

### CROSS-REFERENCE TO RELATED APPLICATIONS

This is a continuation of International Application No. PCT/JP2024/004090 filed on Feb. 7, 2024, and claims priority from Japanese Patent Application No. 2023-030007 filed on Feb. 28, 2023, the entire content of which is incorporated herein by reference.

### TECHNICAL FIELD

The present invention relates to a communication device, a communication method, and a power storage system.

### BACKGROUND ART

There is known a system that collects information about a state of a battery (hereinafter, referred to as state information) and remotely monitors the battery (for example, see Patent Literature 1). The system disclosed in Patent Literature 1 includes various sensors such as a voltage sensor, a current sensor, and a temperature sensor for detecting a state of a battery, a controller to which detection signals of the sensors are input, and a communication interface for communicating state information and the like of the battery input to the controller.

### CITATION LIST

### Patent Literature

Patent Literature 1: JP2020-530256A

### SUMMARY OF INVENTION

### Technical Problem

A case is assumed in which a power storage system is implemented by using storage batteries used in an electric automatic vehicle or storage batteries unused for the electric automatic vehicle and a CAN communication unit for the electric automatic vehicle in which state information of the storage batteries is transmitted via a controller area network (CAN). In this assumption, when the plurality of storage batteries and the plurality of CAN communication units are used in the same vehicle model or are prepared for the same vehicle model, CAN IDs about the same type of data transmitted from the plurality of CAN communication units overlap each other. For example, a CAN ID about a voltage of a certain storage battery and CAN IDs about a voltage of the other storage batteries are the same. Therefore, CAN data frames may collide with each other on a CAN bus, and a state monitoring device may not acquire state information of the plurality of storage batteries.

In view of the above circumstances, an object of the present invention is to provide a communication device, a communication method, and a power storage system in which a CAN data frame including state information of a plurality of storage batteries and a CAN ID is transmitted from the storage batteries to a state monitoring device via a CAN, so that the state monitoring device can acquire the state information of the plurality of storage batteries.

### Solution to Problem

A communication device of the present invention is a communication device that is provided in a power storage system including a plurality of storage batteries and a state monitoring device configured to monitor states of the plurality of storage batteries, and that transmits state information, which is information about the states of the storage batteries, and a first CAN ID for identifying the state information, from the storage batteries to the state monitoring device via a CAN (Controller Area Network), the communication device including: a conversion unit configured to convert the first CAN ID into a first identifier for identifying the state information and the storage batteries, in which the conversion unit has storage battery identification information for identifying the storage batteries, and the conversion unit is configured to execute a first generation process for generating the first identifier based on the first CAN ID received from the storage batteries and the storage battery identification information, a second generation process for generating first reference information indicating a relation among the storage battery identification information, the first identifier, and the state information and referenced by the state monitoring device based on the storage battery identification information, the first identifier generated in the first generation process, and the first CAN ID and the state information received from the storage batteries, and a first conversion process for converting the first CAN ID into the first identifier.

A communication method of the present invention is a communication method for transmitting, in a power storage system including a plurality of storage batteries and a state monitoring device configured to monitor states of the plurality of storage batteries, state information, which is information about the states of the storage batteries, and a CAN ID for identifying the state information, from the storage batteries to the state monitoring device via a CAN, the communication method including: a first generation step of generating an identifier for identifying the state information and the storage batteries based on the CAN ID received from the storage batteries and storage battery identification information for identifying the storage batteries; a second generation step of generating reference information indicating a relation among the storage battery identification information, the identifier, and the state information and referenced by the state monitoring device based on the storage battery identification information, the identifier generated in the first generation step, and the CAN ID and the state information received from the storage batteries; and a conversion step of converting the CAN ID into the identifier.

A power storage system of the present invention is a power storage system including: a plurality of storage batteries; a state monitoring device configured to monitor states of the plurality of storage batteries; and a communication device configured to transmit state information, which is information about the states of the storage batteries, and a CAN ID for identifying the state information, from the storage batteries to the state monitoring device via a CAN, in which the communication device includes a conversion unit configured to convert the CAN ID into an identifier for identifying the state information and the storage batteries, the conversion unit has storage battery identification information for identifying the storage batteries, and the conversion unit is configured to execute a first generation process for generating the identifier based on the CAN ID received from the storage batteries and the storage battery identification information, a second generation process for generating reference information indicating a relation among the storage battery identification information, the identifier, and the state information and referenced by the state monitoring device based on the storage battery identification information, the identifier generated in the first generation process, and the CAN ID and the state information received from the storage batteries, and a conversion process for converting the CAN ID into the identifier.

### Advantageous Effects of Invention

According to the present invention, in the power storage system in which the CAN data frame including the state information of the plurality of storage batteries and the CAN ID is transmitted from the storage batteries to the state monitoring device via the CAN, the state monitoring device can acquire the state information of the plurality of storage batteries.

### BRIEF DESCRIPTION OF DRAWINGS

FIG. 1 is a circuit diagram illustrating a circuit configuration of a power storage system including a communication device according to an embodiment of the present invention.

FIG. 2 is a functional block diagram illustrating an example of functions implemented by the communication device illustrated in FIG. 1.

FIG. 3 is a table illustrating an example of CAN IDs and data included in a CAN data frame transmitted from a battery.

FIG. 4 is a table illustrating an example of a CAN ID conversion table illustrated in FIG. 2.

FIG. 5 is a table illustrating an example of a BMS ID table illustrated in FIG. 2.

FIG. 6 is a flowchart illustrating an example of a procedure for generating a CAN ID conversion table and a BMS ID table.

FIG. 7 is a flowchart illustrating communication between a battery and a BMS.

### DESCRIPTION OF EMBODIMENTS

Hereinafter, the present invention will be described with reference to preferred embodiments. The present invention is not limited to the embodiments to be described below, and the embodiments can be appropriately modified without departing from the gist of the present invention. In the embodiments to be described below, a part of configurations may be not described or shown in the drawings, and regarding details of the omitted techniques, publicly known or well-known techniques will be appropriately applied as long as there is no contradiction with the contents to be described below.

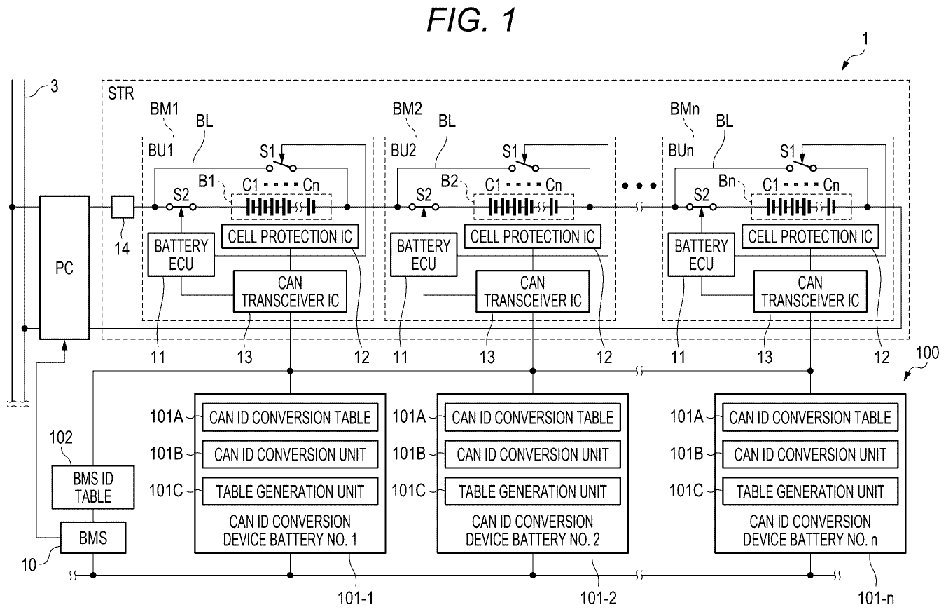

FIG. 1 is a circuit diagram illustrating a circuit configuration of a power storage system 1 including a communication device 100 according to an embodiment of the present invention. The power storage system 1 illustrated in FIG. 1 is a stationary or in-vehicle power supply, and includes a plurality of strings STR or a single string STR, a power converter PC, and a battery management system (BMS) 10. When there are a plurality of strings STR, the plurality of strings STR are connected in parallel.

The string STR includes a plurality of batteries B1 to Bn connected in series. Each of the batteries B1 to Bn includes a plurality of cells C1 to Cn connected in series. The batteries B1 to Bn of the present embodiment are used in an electric automatic vehicle and collected, or are prepared for the electric automatic vehicle and are unused. Therefore, there may be differences in a degree of deterioration among the batteries B1 to Bn. The batteries B1 to Bn are lithium ion batteries or the like, and are discharged through the power converter PC (to be described later) to supply power to an external system (not illustrated). The external system includes a load, a power generator, and the like. When the power storage system 1 is a stationary power supply, home appliances, a commercial power supply system, and the like serve as loads, and a solar photovoltaic power generation system and the like serve as a power generator. On the other hand, when the power storage system 1 is an in-vehicle power supply, a driving motor, an air conditioner, various in-vehicle electrical components, and the like serve as loads. The driving motor serves as both a load and a power generator. On the other hand, power generated by the power generator is supplied to the batteries B1 to Bn through the power converter PC, and the batteries B1 to Bn are charged.

The string STR includes a plurality of battery modules BM1 to BMn and a current sensor 14. The battery modules BM1 to BMn include batteries B1 to Bn, battery electronic control units (ECUs) 11, cell protection integrated circuits (ICs) 12, CAN transceiver ICs 13, and bypass units BU1 to BUn, respectively. The batteries B1 to Bn, the cell protection ICs 12, and the CAN transceiver ICs 13 are used in an electric automatic vehicle and collected, or are prepared for the electric automatic vehicle and unused.

The battery ECUs 11 detect states of the batteries B1 to Bn, determine the states of the batteries B1 to Bn, and control the bypass units BU1 to BUn. The cell protection IC 12 detects overcharge, overdischarge, discharge overcurrent, and charge overcurrent of the cells C1 to Cn, detects and interrupts a short-circuit current, detects a disconnection, recovers the cells C1 to Cn from an overcharged state or an overdischarged state, and balances the cells C1 to Cn.

The battery ECUs 11 transmit information about the states of the batteries B1 to Bn (hereinafter referred to as battery state information) to the CAN transceiver ICs 13. On the other hand, the battery ECUs 11 receive information about the control of the batteries B1 to Bn (hereinafter referred to as battery control information) from the CAN transceiver ICs 13. Examples of the battery state information transmitted from the battery ECUs 11 include a state of charge (SOC). In addition, examples of the battery control information received by the battery ECUs 11 include a voltage instruction value, a current instruction value, and the control information (ON/OFF of switches S1 and S2 to be described later) of the bypass units BU1 to BUn.

The cell protection IC 12 transmits the battery state information to the CAN transceiver IC 13 and receives the battery control information from the CAN transceiver IC 13. Examples of the battery state information transmitted from the cell protection ICs 12 include voltages of the cells C1 to Cn, and a current of the batteries B1 to Bn. In addition, examples of the battery control information received by the cell protection ICs 12 include a voltage instruction value and a current instruction value.

The CAN transceiver IC 13 transmits the battery state information to the BMS 10 via CAN communication performed by the communication device 100, and receives the battery control information from the BMS 10. The communication device 100 will be described later.

The power converter PC is a bidirectional converter and is connected to a string bus 3. In addition, the power converter PC is connected to a positive electrode of the starting battery B1 and a negative electrode of the ending battery Bn.

When the string STR is charged, the power converter PC converts a voltage input from the string bus 3 according to an instruction value of charge power (or charge current) and outputs the converted voltage to the plurality of batteries B1 to Bn. Here, the voltage on the string STR changes according to a bypass state of the batteries B1 to Bn (number of bypassed batteries B1 to Bn) and a charging state of the batteries B1 to Bn. Therefore, when the string STR is charged, the power converter PC converts the voltage input from the string bus 3 into the voltage on the string STR and outputs the converted voltage to the plurality of batteries B1 to Bn.

When the string STR is discharged, the power converter PC converts the voltage input from the plurality of batteries B1 to Bn according to an instruction value of discharge power (or discharge current) and outputs the converted voltage to the string bus 3. Here, the input voltage of the power converter PC during discharge changes according to the bypass state of the batteries B1 to Bn or the charging state of the batteries B1 to Bn. Accordingly, when the plurality of strings STR are operated in parallel, variations occur in the input voltage of the power converter PC among the strings STR during discharge. Therefore, when the string STR is discharged, the power converter PC converts the input voltage into a voltage that matches the other strings STR and outputs the converted voltage to the string bus 3. When the current flowing through the string bus 3 is an alternating current, the power converter PC includes a synchronization unit for following a change in an instantaneous value.

The bypass units BU1 to BUn are provided for the batteries B1 to Bn, respectively. Each of the bypass units BU1 to BUn includes a bypass line BL and the switches S1 and S2. The bypass line BL is a power line that bypasses each of the batteries B1 to Bn. The switch S1 is provided on the bypass line BL. The switch S1 is, for example, a mechanical switch, a semiconductor switch, or a relay. The switch S2 is provided between a positive electrode of each of the batteries B1 to Bn and one end of the bypass line BL. The switch S2 is, for example, a mechanical switch, a semiconductor switch, or a relay.

The starting battery B1 and the ending battery Bn are connected to an external system via the power converter PC and the string bus 3. When the switch S1 is turned off and the switch S2 is turned on in all the bypass units BU1 to BUn, all the batteries B1 to Bn are connected in series. On the other hand, when the switch S2 is turned off and the switch S1 is turned on in any one of the bypass units BU1 to BUn, the batteries B1 to Bn corresponding to the bypass units BU1 to BUn are bypassed.

The current sensor 14 is provided on the power line of the string STR. The current sensor 14 detects a charge and discharge current of the string STR and transmits a detection signal to the BMS 10. In addition, the string STR is provided with a voltage sensor, a temperature sensor, and the like (not illustrated). The voltage sensor detects a total voltage of the string STR and transmits a detection signal to the BMS 10. In addition, the temperature sensor detects an ambient temperature of the string STR and transmits a detection signal to the BMS 10.

The BMS 10 communicates with a host controller (not illustrated), the plurality of battery ECUs 11, and the plurality of cell protection ICs 12, and controls and manages the plurality of battery modules BM1 to BMn. In addition, the BMS 10 controls and manages auxiliary equipment provided in the string STR. Examples of the auxiliary equipment include the power converter PC and the current sensor 14.

Based on the battery state information received from the battery ECUs 11 and the cell protection ICs 12 via a CAN, the BMS 10 monitors the states of the batteries B1 to Bn and generates and transmits the battery control information. The battery control information includes information about the control of the bypass units BU1 to BUn, and information about voltage instruction values and current instruction values of the batteries B1 to Bn. Here, the BMS 10 receives an instruction value for charge and discharge power (or charge and discharge current) of the string STR from the host controller, and calculates the voltage instruction values and the current instruction values of the batteries B1 to Bn based on the instruction value for the charge and discharge power and the state information of the batteries B1 to Bn. In addition, the BMS 10 determines whether a request for the control of the bypass units BU1 to BUn transmitted from the battery ECUs 11 is permitted, and transmits bypass control information according to the determination result to the battery ECUs 11.

The communication device 100 includes a plurality of CAN ID conversion devices 101-1 to 101-n and a BMS ID table 102. The CAN ID conversion devices 101-1 to 101-n are provided for the respective battery modules BM1 to BMn. It is not essential to provide the plurality of CAN ID conversion devices 101-1 to 101-n and make the CAN ID conversion devices 101-1 to 101-n correspond to the battery modules BM1 to BMn in a one-to-one manner. One CAN ID conversion device may be provided with a plurality of input and output terminals, and the input and output terminals may correspond to the battery modules BM1 to BMn in a one-to-one manner.

Each of the CAN ID conversion devices 101-1 to 101-n includes a CAN ID conversion table 101A, a CAN ID conversion unit 101B, and a table generation unit 101C. The CAN ID conversion table 101A is a table referenced when CAN IDs included in a CAN data frame are converted into BMS IDs to be described later.

The CAN ID conversion unit 101B converts the CAN IDs included in the CAN data frame transmitted from the CAN transceiver IC 13 into the BMS IDs with reference to the CAN ID conversion table 101A, and transmits the converted CAN data frame to the BMS 10. On the other hand, the CAN ID conversion unit 101B converts the BMS IDs included in the CAN data frame transmitted from the BMS 10 into the CAN IDs with reference to the CAN ID conversion table 101A, and transmits the converted CAN data frame to the CAN transceiver IC 13.

Each table generation unit 101C generates each CAN ID conversion table 101A and the BMS ID table 102. The BMS ID table 102 is a table referenced when the BMS 10 identifies the battery state information and the batteries B1 to Bn at the time of receiving the CAN data frame from each of the CAN ID conversion devices 101-1 to 101-n. In addition, the BMS ID table 102 is also a table referenced when the BMS 10 generates the battery control information.

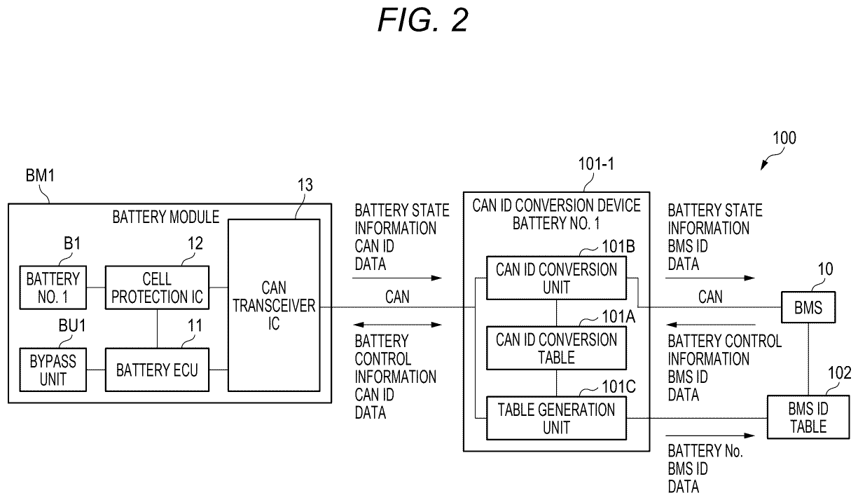

FIG. 2 is a functional block diagram illustrating an example of functions implemented by the communication device 100 illustrated in FIG. 1. FIG. 2 illustrates communication between the battery module BM1 and the BMS 10, and communication between the other battery modules BM2 to BMn and the BMS 10 is also performed in a similar manner.

The CAN ID conversion device 101-1 illustrated in FIG. 2 is installed between the battery module BM1 and the BMS 10 when the battery B1 is newly connected to the power storage system 1 (see FIG. 1). Here, in the present embodiment, the battery B1, the cell protection IC 12, and the CAN transceiver IC 13 are used in the electric automatic vehicle or prepared for the electric automatic vehicle. In contrast, the bypass unit BU1, the battery ECU 11, and the CAN ID conversion device 101-1 are newly installed. When the battery module BM1 including the bypass unit BU1 is used, the bypass unit BU1 may also be used. In addition, when the battery ECU 11 can be reused, there is no need to newly install the bypass unit BU1, the battery ECU 11, and the CAN ID conversion device 101-1.

As illustrated in FIG. 2, the CAN data frame including the CAN IDs and the battery state information is transmitted from the CAN transceiver IC 13 to the CAN ID conversion device 101-1 via the CAN.

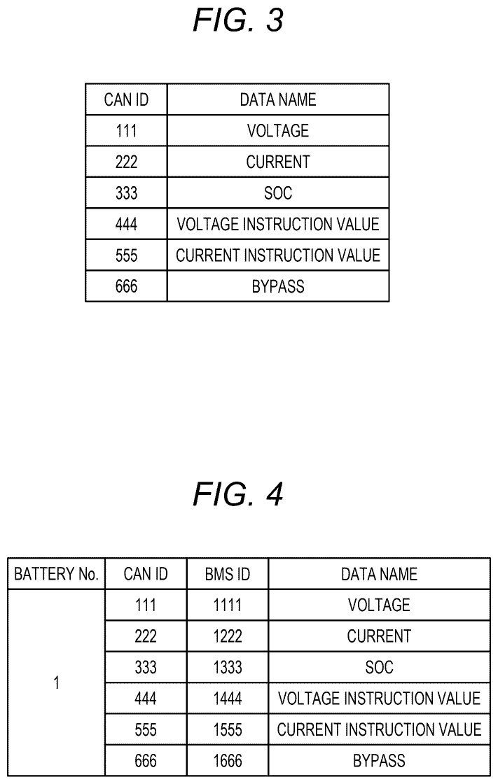

FIG. 3 is a table illustrating an example of CAN IDs and data included in the CAN data frame transmitted from the battery B1. As illustrated in this table, the CAN data frame transmitted from the battery B1 includes data such as voltage, current, SOC, voltage instruction value, current instruction value, control information on the bypass unit BU1, and the CAN IDs for identifying the data. The voltage, the current, and the SOC correspond to the battery state information, and the voltage instruction value, the current instruction value, and the control information of the bypass unit BU1 correspond to the battery control information.

Here, the CAN IDs for identifying the state information and the control information of the batteries B1 to Bn are set for each vehicle model. Therefore, for example, when the battery B1 and the battery B2 are batteries for the same vehicle model, the CAN IDs for identifying the battery state information and the battery control information overlap between the battery B1 and the battery B2. For example, the CAN IDs for identifying the voltage of the battery B1 and the voltage of the battery B2 are the same. Accordingly, the CAN data frame transmitted from the battery B1 and the CAN data frame transmitted from the battery B2 may collide with each other on a CAN bus and may not be acquired by the BMS 10.

Therefore, in the present embodiment, as illustrated in FIG. 2, the CAN ID conversion device 101-1 converts the CAN ID included in the CAN data frame received from the battery B1 into the BMS ID that can be identified by the BMS 10. The CAN ID conversion device 101-1 converts the CAN ID into the BMS ID with reference to the CAN ID conversion table 101A.

On the other hand, the CAN ID conversion device 101-1 converts the BMS ID included in the CAN data frame received from the BMS 10 to the CAN ID that can be identified on the battery B1. The CAN ID conversion device 101-1 converts the BMS ID into the CAN ID with reference to the CAN ID conversion table 101A.

FIG. 4 is a table illustrating an example of the CAN ID conversion table 101A illustrated in FIG. 2. As illustrated in this table, the CAN ID conversion table 101A is a table indicating a correspondence among a battery No., CAN IDs, BMS IDs, and data. This table illustrates the CAN ID conversion table 101A corresponding to the battery B1 whose battery No. is 1. The CAN ID conversion table 101A illustrated in this table is stored in the CAN ID conversion device 101-1 connected to the battery module BM1 via the CAN. The CAN ID conversion table 101A corresponding to the other battery Nos., that is the batteries B2 to Bn has different battery Nos. and BMS IDs from the CAN ID conversion table 101A illustrated in the table of FIG. 4.

As illustrated in the table of FIG. 4, the CAN IDs in the CAN ID conversion table 101A match the CAN IDs included in the CAN data frame illustrated in the table of FIG. 3. On the other hand, the BMS IDs of the CAN ID conversion table 101A are set such that the battery Nos. and types of data can be identified.

As illustrated in FIG. 2, the CAN ID conversion device 101-1 includes the CAN ID conversion table 101A, the CAN ID conversion unit 101B, and the table generation unit 101C. The CAN ID conversion unit 101B converts the CAN IDs into the BMS IDs with reference to the CAN ID conversion table 101A when receiving the CAN data frame from the CAN transceiver IC 13. Then, the CAN ID conversion unit 101B transmits the CAN data frame after the ID conversion to the BMS 10. On the other hand, the CAN ID conversion unit 101B converts the BMS IDs into the CAN IDs with reference to the CAN ID conversion table 101A when receiving the CAN data frame from the BMS 10. Then, the CAN ID conversion unit 101B transmits the CAN data frame after the ID conversion to the CAN transceiver IC 13.

The table generation unit 101C generates the BMS IDs, the CAN ID conversion table 101A, and the BMS ID table 102. The BMS ID table 102 is a table referenced when the BMS 10 receives the CAN data frame including the battery state information, and when the BMS 10 generates the CAN data frame including the battery control information.

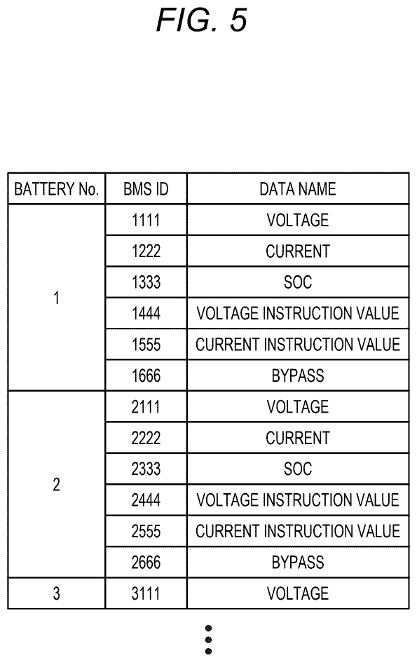

FIG. 5 is a table illustrating an example of the BMS ID table 102 illustrated in FIG. 2. As illustrated in this table, the BMS ID table 102 is a table indicating a correspondence among battery Nos., BMS IDs, and data (battery state information and battery control information). This table illustrates the BMS IDs and the data corresponding to the battery B1, whose battery No. is 1, and the BMS IDs and the data corresponding to the battery B2, whose battery No. is 2. The BMS ID table 102 illustrated in this table is stored in the BMS 10, the host controller, or an external server (not illustrated).

The table generation unit 101C illustrated in FIG. 2 stores battery No. information for identifying the batteries B1 to Bn. When new batteries B1 to Bn are connected, the table generation unit 101C acquires a CAN data frame from the CAN transceiver IC 13. Then, the table generation unit 101C generates BMS IDs based on CAN IDs included in the acquired CAN data frame and the battery No. information stored in advance. The table generation unit 101C generates the CAN ID conversion table 101A based on the CAN IDs and the data included in the acquired CAN data frame and the generated BMS IDs. Furthermore, the table generation unit 101C generates the BMS ID table 102 based on the CAN IDs and the data included in the acquired CAN data frame, the battery No. information stored in advance, and the generated BMS IDs.

The BMS 10 identifies the types of data corresponding to the BMS IDs included in the CAN data frame with reference to the BMS ID table 102 when receiving the CAN data frame from the CAN ID conversion device 101-1. On the other hand, the BMS 10 stores the battery control information and the BMS IDs in the CAN data frame in association with each other with reference to the BMS ID table 102 when generating the battery control information.

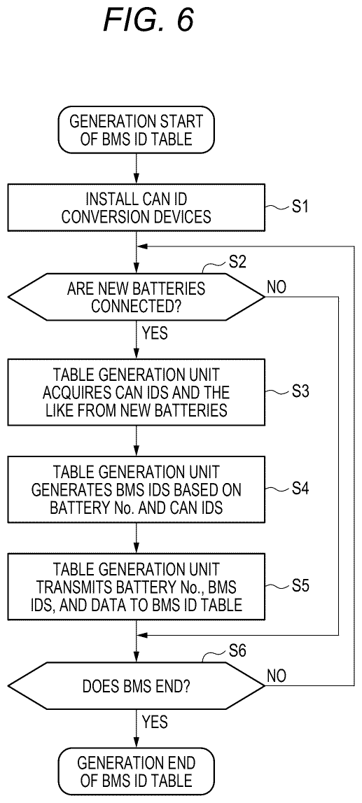

FIG. 6 is a flowchart illustrating an example of a procedure for generating the CAN ID conversion table 101A and the BMS ID table 102. The BMS ID table 102 illustrated in the flowchart is generated when the new batteries B1 to Bn are connected to the power storage system 1.

First, in step S1, an operator installs the CAN ID conversion devices 101-1 to 101-n corresponding to the newly connected batteries B1 to Bn between the battery modules BM1 to BMn and the BMS 10. The installed CAN ID conversion devices 101-1 to 101-n store the battery No. information of the newly connected batteries B1 to Bn.

Next, in step S2, the table generation unit 101C determines whether the new batteries B1 to Bn are connected to the power storage system 1 based on whether the CAN data frame is received from the battery modules BM1 to BMn. If the determination is yes in step S2, the process proceeds to step S3, and if the determination is no in step S2, the process proceeds to step S6.

In step S3, the table generation unit 101C acquires a CAN data frame including various data and CAN IDs from the CAN transceiver ICs 13 corresponding to the new batteries B1 to Bn. Here, the “various data” includes the battery state information and the battery control information. The CAN ID for identifying the battery state information corresponds to a first CAN ID, and the CAN ID for identifying the battery control information corresponds to a second CAN ID.

Next, in step S4, the table generation unit 101C generates BMS IDs based on the stored battery No. information and the CAN IDs included in the CAN data frame received from the CAN transceiver IC 13. The BMS IDs generated in step S4 include a first identifier for identifying the batteries B1 to Bn and the type of battery state information, and a second identifier for identifying the batteries B1 to Bn and the type of battery control information.

Next, in step S5, the table generation unit 101C transmits, to the BMS ID table 102, the BMS IDs generated in step S4, the battery state information and the battery control information identified by the BMS IDs, and the battery No. information. Accordingly, the BMS ID table 102 corresponding to the newly connected batteries B1 to Bn is generated. The above process in steps S2 and S5 is repeated while the BMS 10 is operating (NO in step S6), and ends together with the end of the operation of the BMS 10 (YES in step S6).

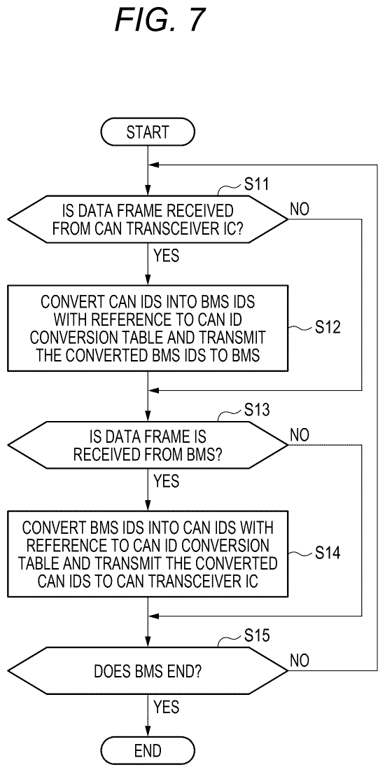

FIG. 7 is a flowchart illustrating communication between the batteries B1 to Bn and the BMS 10. The process illustrated in the flowchart is started together with the start of operation of the BMS 10.

First, in step S11, the CAN ID conversion unit 101B determines whether the CAN data frame is received from the CAN transceiver IC 13. If the determination is yes in step S11, the process proceeds to step S12, and if the determination is no in step S11, the process proceeds to step S13.

In step S12, the CAN ID conversion unit 101B converts the CAN IDs included in the CAN data frame received from the CAN transceiver IC 13 into the BMS IDs with reference to the CAN ID conversion table 101A. Then, the CAN ID conversion unit 101B transmits the CAN data frame after the ID conversion to the BMS 10.

Next, in step S13, the CAN ID conversion unit 101B determines whether the CAN data frame is received from the BMS 10. If the determination is yes in step S13, the process proceeds to step S14, and if the determination is no in step S13, the process proceeds to step S15.

In step S14, the CAN ID conversion unit 101B converts the BMS IDs included in the CAN data frame received from the BMS 10 into the CAN IDs with reference to the CAN ID conversion table 101A. At this time, the CAN ID conversion unit 101B receives only the CAN data frame including the BMS IDs included in the CAN ID conversion table 101A, and converts the BMS IDs into the CAN IDs on the received CAN data frame. Then, the CAN ID conversion unit 101B transmits the CAN data frame after the ID conversion to the CAN transceiver IC 13. The above process in steps S11 and S14 is repeated while the BMS 10 is operating (NO in step S15), and ends together with the end of the operation of the BMS 10 (YES in step S15).

As described above, the communication device 100 of the present embodiment includes the CAN ID conversion devices 101-1 to 101-n. The CAN ID conversion devices 101-1 to 101-n have the battery No. information for identifying the batteries B1 to Bn.

Here, when the new batteries B1 to Bn are connected, the CAN ID conversion devices 101-1 to 101-n acquire the CAN IDs about the battery state information from the batteries B1 to Bn. Next, the CAN ID conversion devices 101-1 to 101-n generate the BMS IDs for identifying the battery state information and the batteries B1 to Bn based on the CAN IDs acquired from the batteries B1 to Bn and the battery No. information (first generation process).

Next, the CAN ID conversion devices 101-1 to 101-n generate the BMS ID table 102 indicating a relation among the battery No., the BMS IDs, and the battery state information based on the battery No. information, the generated BMS IDs, and the CAN IDs and the battery state information received from the batteries B1 to Bn (second generation process).

When the CAN data frame including the battery state information and the CAN IDs is transmitted from the batteries B1 to Bn to the BMS 10, the CAN ID conversion devices 101-1 to 101-n convert the CAN IDs into the BMS IDs (first conversion process). In the process, the CAN ID conversion table 101A indicating a relation between the CAN IDs and the BMS IDs is referenced. Then, the CAN ID conversion devices 101-1 to 101-n transmit the CAN data frame after the ID conversion to the BMS 10.

Accordingly, even when the power storage system 1 is implemented by using the batteries B1 to Bn for the same vehicle model, it is possible to prevent the CAN IDs about the same type of battery state information transmitted from the different battery modules BM1 to BMn from overlapping. Accordingly, the CAN data frames transmitted from the different battery modules BM1 to BMn can be acquired by the BMS 10 without collision on the CAN bus. Then, the BMS 10 can identify which of the batteries B1 to Bn the battery state information included in the acquired CAN data frame corresponds to with reference to the BMS ID table 102.

In addition, in the communication device 100 of the present embodiment, the CAN ID conversion table 101A serves as reference information indicating a relation among the battery No. information, the CAN IDs about the battery control information, and the BMS IDs about the control information of the batteries B1 to Bn.

Here, when the new batteries B1 to Bn are connected, the CAN ID conversion devices 101-1 to 101-n acquire the CAN IDs about the battery control information from the batteries B1 to Bn. Next, the CAN ID conversion devices 101-1 to 101-n generate the BMS IDs about the battery control information based on the CAN IDs about the battery control information and the battery No. information (third generation process).

Next, the CAN ID conversion devices 101-1 to 101-n generate the BMS ID table 102 indicating a relation among the battery No. information, the BMS IDs, and the battery control information based on the battery No. information, the generated BMS IDs, and the CAN IDs and the battery control information received from the batteries B1 to Bn (fourth generation process).

When the CAN data frame including the battery control information and the CAN IDs is transmitted from the BMS 10 to the batteries B1 to Bn, the CAN ID conversion devices 101-1 to 101-n convert the BMS IDs into the CAN IDs (second conversion process). In the process, the CAN ID conversion table 101A indicating a relation between the CAN IDs and the BMS IDs is referenced. Then, the CAN ID conversion devices 101-1 to 101-n transmit the CAN data frame after the ID conversion to the batteries B1 to Bn.

Accordingly, even when the power storage system 1 is implemented by using the batteries B1 to Bn for the same vehicle model, it is possible to prevent the CAN IDs about the same type of battery control information transmitted from the BMS 10 to the different battery modules BM1 to BMn from overlapping. Accordingly, the CAN data frames transmitted from the BMS 10 to the different battery modules BM1 to BMn can be acquired by the battery modules BM1 to BMn without collision on the CAN bus. Then, the BMS 10 can identify which of the battery modules BM1 to BMn the battery control information included in the CAN data frame to be transmitted corresponds to with reference to the BMS ID table 102.

Although the present invention has been described above based on the above embodiments, the present invention is not limited to the above embodiments. Modifications may be made without departing from the gist of the present invention, or publicly known or well-known techniques may be appropriately combined.

For example, in the above embodiments, a storage battery is a battery, and the storage battery may be another secondary battery such as a capacitor. In addition, in the above embodiments, the CAN ID conversion table 101A and the BMS ID table 102 are generated at the timing when the batteries B1 to Bn are newly connected. However, the connection of the new batteries B1 to Bn may be confirmed at predetermined time intervals, and the CAN ID conversion table 101A and the BMS ID table 102 may be generated when the connection is confirmed.

Although various embodiments have been described above, it is needless to say that the present invention is not limited to these examples. It is apparent that those skilled in the art can come up with various modifications or corrections within the scope of the claims, and it is understood that the modifications or corrections naturally fall within the technical scope of the present invention. In addition, components described in the above embodiments may be combined freely without departing from the spirit of the invention.

The present application is based on a Japanese patent application (No. 2023-30007) filed on Feb. 28, 2023, the contents of which are incorporated herein by reference.

### REFERENCE SIGNS LIST

1: power storage system
10: BMS (state monitoring device)
100: communication device
101-1 to 101-n: CAN ID conversion device (conversion unit)
102: BMS ID table (first reference information, second reference information, reference information)
B1 to Bn: battery (storage battery)

1. A communication device that is provided in a power storage system including a plurality of storage batteries and a state monitoring device configured to monitor states of the plurality of storage batteries, and that transmits state information, which is information about the states of the storage batteries, and a first CAN ID for identifying the state information, from the storage batteries to the state monitoring device via a CAN (Controller Area Network), the communication device comprising:
a conversion unit configured to convert the first CAN ID into a first identifier for identifying the state information and the storage batteries, wherein
the conversion unit has storage battery identification information for identifying the storage batteries, and
the conversion unit is configured to execute
a first generation process for generating the first identifier based on the first CAN ID received from the storage batteries and the storage battery identification information,
a second generation process for generating first reference information indicating a relation among the storage battery identification information, the first identifier, and the state information and referenced by the state monitoring device based on the storage battery identification information, the first identifier generated in the first generation process, and the first CAN ID and the state information received from the storage batteries, and
a first conversion process for converting the first CAN ID into the first identifier.

2. The communication device according to claim 1, wherein
control information that is information about control of the storage batteries and a second identifier for identifying the control information and the storage batteries are transmitted from the state monitoring device to the storage batteries via the CAN, and
the conversion unit is configured to execute
a third generation process for receiving a second CAN ID for identifying the control information from the storage batteries, and generating the second identifier based on the second CAN ID and the storage battery identification information,
a fourth generation process for generating second reference information indicating a relation among the storage battery identification information, the second identifier, and the control information and referenced by the state monitoring device based on the storage battery identification information, the second identifier generated in the third generation process, and the second CAN ID and the control information received from the storage batteries, and
a second conversion process for converting the second identifier into the second CAN ID.

3. A communication method for transmitting, in a power storage system including a plurality of storage batteries and a state monitoring device configured to monitor states of the plurality of storage batteries, state information, which is information about the states of the storage batteries, and a CAN ID for identifying the state information, from the storage batteries to the state monitoring device via a CAN, the communication method comprising:
a first generation step of generating an identifier for identifying the state information and the storage batteries based on the CAN ID received from the storage batteries and storage battery identification information for identifying the storage batteries;
a second generation step of generating reference information indicating a relation among the storage battery identification information, the identifier, and the state information and referenced by the state monitoring device based on the storage battery identification information, the identifier generated in the first generation step, and the CAN ID and the state information received from the storage batteries; and
a conversion step of converting the CAN ID into the identifier.

4. A power storage system comprising:
a plurality of storage batteries;
a state monitoring device configured to monitor states of the plurality of storage batteries; and
a communication device configured to transmit state information, which is information about the states of the storage batteries, and a CAN ID for identifying the state information, from the storage batteries to the state monitoring device via a CAN, wherein
the communication device includes a conversion unit configured to convert the CAN ID into an identifier for identifying the state information and the storage batteries,
the conversion unit has storage battery identification information for identifying the storage batteries, and
the conversion unit is configured to execute
a first generation process for generating the identifier based on the CAN ID received from the storage batteries and the storage battery identification information,
a second generation process for generating reference information indicating a relation among the storage battery identification information, the identifier, and the state information and referenced by the state monitoring device based on the storage battery identification information, the identifier generated in the first generation process, and the CAN ID and the state information received from the storage batteries, and
a conversion process for converting the CAN ID into the identifier.
